(19) United States
(12) Patent Application Publication
(10) Pub. No.: US 2007/0085090 A1
(43) Pub. Date: Apr. 19, 2007

(54) Active matrix driving display device and method of manufacturing the same

(75) Inventors: Yong Hae Kim, Gyeonggi (KR); Choong Heui Chung, Daejeon (KR); Jin Ho Lee, Daejeon (KR)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(73) Assignee: Electronics and Telecommunications Research Institute

(21) Appl. No.: 11/450,109

(22) Filed: Jun. 8, 2006

(30) Foreign Application Priority Data
Oct. 14, 2005 (KR) 2005-96772

(51) Int. Cl. H01L 31/12

(52) U.S. Cl. 257/83

(57) ABSTRACT

Provided are an active matrix driving display device and a method of manufacturing the same. The active matrix driving display device includes: a first buffer layer formed on a plastic substrate; a laser-absorbing layer formed on the first buffer layer; a second buffer layer formed on the laser-absorbing layer; and an active layer formed on the second buffer layer, whereby it is possible to prevent deformation of the plastic substrate even when light or heat is used during the formation of the active layer.

### CROSS-REFERENCE TO RELATED APPLICATION

This application claims priority to and the benefit of Korean Patent Application No. 2005-96772, filed on Oct. 14, 2005, the disclosure of which is incorporated herein by reference in its entirety.

### BACKGROUND

1. Field of the Invention

The present invention relates to an active matrix driving display device and a method of manufacturing the same, and more particularly, to an active matrix driving display device manufactured using a plastic substrate and a method of manufacturing the same.

2. Discussion of Related Art

FIG. 1 is a partial cross-sectional view of an active matrix driving display device formed on a glass substrate. Referring to FIG. 1, the active matrix driving display device 100 includes a substrate 110, a thin film transistor 120 having an active layer 121 (referred to as so called “semiconductor layer”) formed on the substrate 110, a capacitor 130, and a light emitting diode 140. The substrate 110 constituting the active matrix driving display device 100 may be formed of glass, plastic, or the like, and a glass substrate is used in FIG. 1. A buffer layer 111 may be formed on the glass substrate 110 to prevent impurities such as metal ions from diffusing to the active layer 121.

The thin film transistor 120 having the active layer 121, a gate electrode 123, a source electrode 125, and a drain electrode 127 is formed on the buffer layer 111. The active layer 121 constituting the thin film transistor 120 is formed by depositing an amorphous silicon layer using various deposition processes (for example, chemical vapor deposition (CVD), sputtering, and so on), crystallizing the deposited amorphous silicon layer using a predetermined method (for example, a lithography method, a laser method, and so on), and then performing an ion doping process.

A gate insulating layer 112 is formed on the active layer 121, and a gate metal layer is deposited on the gate insulating layer 112 and then patterned to form a gate electrode 123. At this time, a first electrode 131 of the capacitor 130 is formed together with the gate electrode 123. An interlayer insulating layer 113 is formed on the gate electrode 123, and first contact holes (not shown) are formed in the interlayer insulating layer 113. Next, the source electrode 125 and the drain electrode 127 which are in electrical contact with the active layer 121 through the contact holes are formed on the interlayer insulating layer 113. At this time, a second electrode 133 of the capacitor 130 may be formed together with the source electrode 125 and the drain electrode 127.

A passivation layer 114 is formed on the thin film transistor 120 and the capacitor 130, and a second contact hole (not shown) is formed on the passivation layer 114. An organic light emitting diode 140, which is electrically connected to the thin film transistor through the second contact hole and has a lower electrode 141, an organic emission layer 143, and an upper electrode 145, is formed on the passivation layer 114 having the second contact hole. By sequentially performing the manufacturing processes, the active matrix driving display device is manufactured. While a planarization layer is not described for convenience of description, the planarization layer may be formed on the thin film transistor 120 and the capacitor 130.

As described above, when the active matrix driving display device 100 is manufactured using the glass substrate 110, in order to from the active layer 121 on the glass substrate 110, a lithography method and a laser method may be used after depositing an amorphous silicon layer. Since the glass substrate 110 has a relatively high thermal resistance, even though any one of the lithography method and the laser method is used, the glass substrate 110 is not thermally deformed. In particular, even when the laser method is used to crystallize the amorphous silicon layer, since the laser beam passes through the glass substrate 110, the glass substrate 100 is not thermally deformed.

However, when an active matrix driving display device is manufactured using a glass substrate, since the glass substrate is relatively heavy and fragile, it is difficult to make the active matrix driving display device large as well as to perform the manufacturing itself.

In order to solve the problems due to the use of the glass substrate, recently, a plastic substrate which is thin and lightweight and has flexibility is being widely used. Even though the active matrix driving display device is manufactured using the plastic substrate, various methods such as a lithography method, a laser method, and so on can be used to form an active layer on the substrate.

However, when the active layer is formed by the lithography employing relatively high energy, the plastic substrate may be easily deformed due to the high thermal energy, and therefore it is difficult to form the active layer. In addition, when the active layer is formed on the plastic substrate using the laser method, since the plastic substrate having a transmissivity lower than that of the glass substrate absorbs laser, the plastic substrate may be deformed. In order to solve the problems, the active layer is etched after performing an activation process using the laser method. However, since leakage may occur through ends of the gate electrode, it is difficult to effectively drive the active matrix driving display device.

### SUMMARY OF THE INVENTION

The present invention is directed to an active matrix driving display device capable of reducing thermal deformation of a plastic substrate and protecting the plastic substrate to increase safety and a method of manufacturing the same.

One aspect of the present invention provides an active matrix driving display device including: a first buffer layer formed on a plastic substrate; a laser-absorbing layer formed on the first buffer layer; a second buffer layer formed on the laser-absorbing layer; and an active layer formed on the second buffer layer.

The laser-absorbing layer may have a thickness of 100˜2000 Å, and the laser-absorbing layer may be formed of a material absorbing laser light irradiated from the top of the plastic substrate. The laser-absorbing layer may contain amorphous silicon or molybdenum. In addition, each of the first buffer layer and the second buffer layer may have a thickness of 1000˜5000 Å, and the first buffer layer and the second buffer layer may be formed of oxide or nitride. The active layer may have a melting point relatively higher than that of the first buffer layer, the second buffer layer, and the laser-absorbing layer. The active matrix driving display device may further include: a thin film transistor formed on the active layer and having a gate electrode, a source electrode, and a drain electrode; and a capacitor and a light emitting diode which are electrically connected to the thin film transistor.

Another aspect of the present invention provides a method of manufacturing an active matrix driving display device including forming a first buffer layer on a plastic substrate, forming a laser-absorbing layer on the first buffer layer, forming a second buffer layer on the laser-absorbing layer, and forming an active layer on the second laser-absorbing layer.

Forming the active layer may include depositing an amorphous silicon layer on the second buffer layer, and crystallizing the deposited amorphous silicon layer. The method may further include forming a thin film transistor having the active layer, and a gate electrode, a source electrode, and a drain electrode which are formed on the active layer, and forming a light emitting diode electrically connected to the thin film transistor.

### BRIEF DESCRIPTION OF THE DRAWINGS

The above and other features and advantages of the present invention will become more apparent to those of ordinary skill in the art by describing in detail preferred exemplary embodiments thereof with reference to the attached drawings in which:

FIG. 1 is a partial cross-sectional view of a conventional active matrix driving display device manufactured using a glass substrate;

FIG. 2 is a partial cross-sectional view of an active matrix driving display device manufactured using a plastic substrate in accordance with an embodiment of the present invention;

FIG. 3 is a cross-sectional view showing a process of forming an active layer region of the active matrix driving display device of FIG. 2;

FIG. 4A is an enlarged view of a region (I) in FIG. 3, and FIGS. 4B and 4C are photographs showing a state of deformation of a plastic substrate resulting from different amounts of laser irradiation of the region (I);

FIGS. 5 and 6 are cross-sectional views showing manufacturing processes after the manufacturing process of FIG. 3;

FIG. 7A is an enlarged view of a region (II) in FIG. 5, and FIGS. 7B and 7C are photographs showing a state of deformation of a plastic substrate resulting from different amounts of laser irradiation of the region (II); and

FIG. 8 is a cross-sectional view showing manufacturing processes after the manufacturing process of FIG. 6.

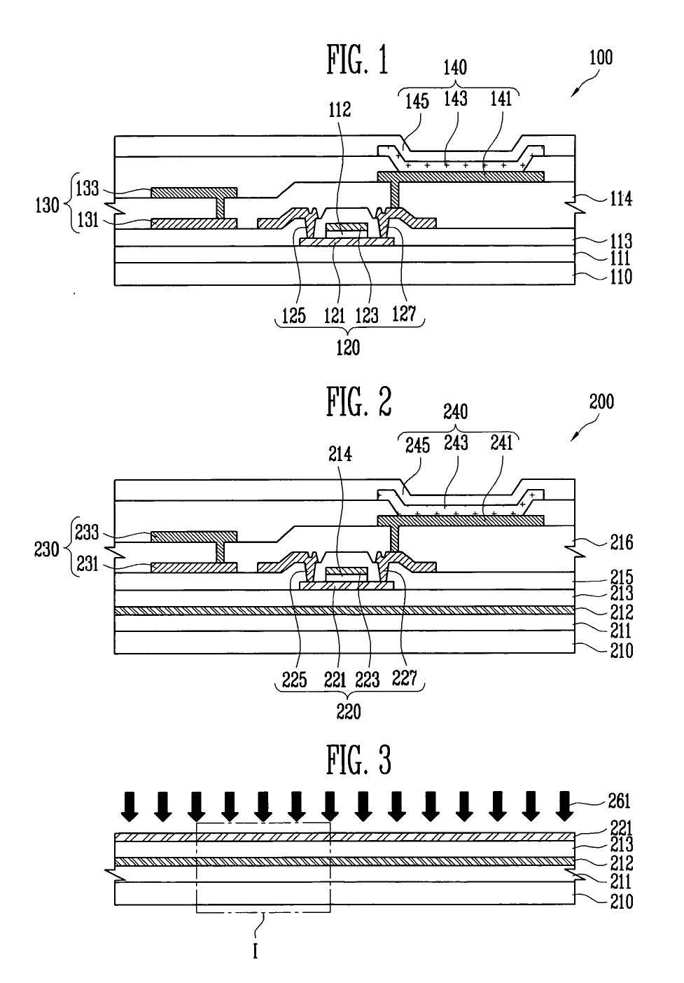

### DETAILED DESCRIPTION OF PREFERRED EMBODIMENTS

A method of manufacturing an active matrix driving display device of the present invention will now be described more fully hereinafter with reference to the accompanying drawings, in which preferred embodiments of the invention are shown.

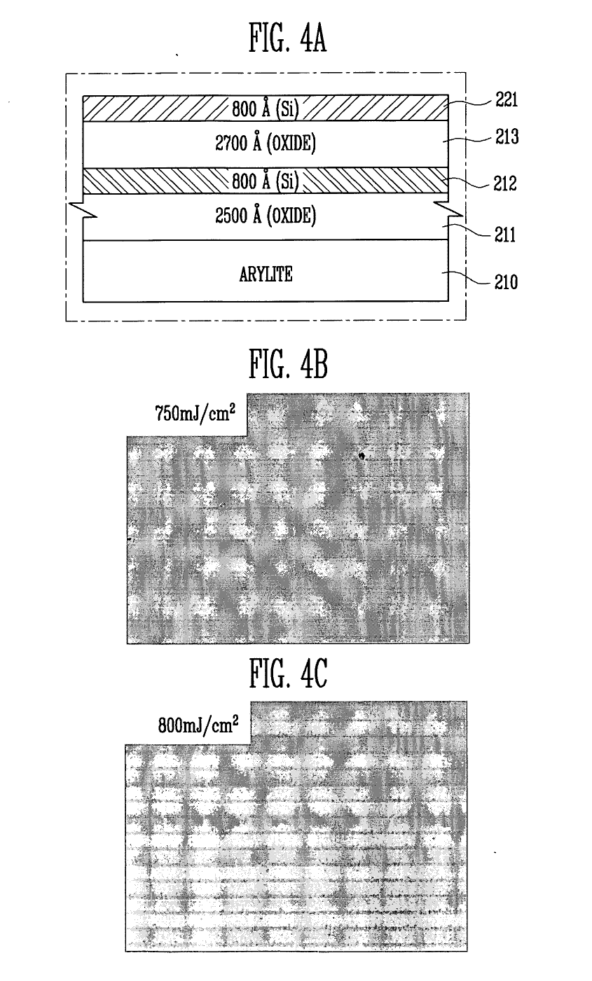

FIG. 2 is a partial cross-sectional view of an active matrix driving display device in accordance with an embodiment of the present invention. Referring to FIG. 2, the active matrix driving display device 200 includes a plastic substrate 210, a thin film transistor 220, a capacitor 230, and an organic light emitting diode 240. The thin film transistor 220 is formed on the plastic substrate 210, and includes an active layer 221, a gate electrode 223, a source electrode 224, and a drain electrode 227. The capacitor 230 is composed of a pair of electrodes 231 and 233, and the organic light emitting diode 240 is electrically connected to the thin film transistor 220, and includes a pixel electrode 241, an organic emission layer 243, and an opposite electrode 245.

FIG. 3 is a cross-sectional view showing a process of forming an active layer region of the active matrix driving display device of FIG. 2. Referring to FIG. 3, in order to manufacture the active matrix driving display device 200 in accordance with the present invention, first, a plastic substrate 210 is prepared. The plastic substrate 210 is formed of a polymer material such as poly(ethyleneterephtalate) (PET), poly(ethylene naphthalate) (PEN), polyimide (Pi), and so on, and the plastic substrate 210 of the embodiment is formed of arylite. A first buffer layer 211 is deposited on the plastic substrate 210. The deposited first buffer layer 211 is formed to a thickness such that the plastic substrate 210 formed under the first buffer layer 211 is not deformed due to external heat, and preferably a thickness of 1000 to 5000 Å.

A laser-absorbing layer 212 is formed on the first buffer layer 211. The laser-absorbing layer 212 functions to absorb heat applied to the plastic substrate 220 during formation of an active layer. The laser-absorbing layer 212 is formed of a material absorbing light or heat well and having a melting point relatively higher than that of the active layer 221, for example, amorphous silicon, molybdenum (Mo), and so on. The laser-absorbing layer 212 is formed to a thickness capable of absorbing heat or light, for example, a thickness of about 100˜2000 Å. Next, a second buffer layer 213 is deposited on the laser-absorbing layer 212. The second buffer layer 213 is formed to a thickness such that the heat or light transmitted from the top is not transmitted to the plastic substrate 210 or minimized, and preferably a thickness of about 100˜5000 Å. The first buffer layer 211 and the second buffer layer 213 are formed of oxide, nitride, or the like. For example, the first buffer layer 211 and the second buffer layer 213 may be formed of SiN, not containing impurities such as argon (Ar), hydrogen (H), and so on.

An amorphous silicon layer to be used as the active layer 221 is deposited on the second buffer layer 213. After the deposition of the amorphous silicon layer, heat or light is applied onto the amorphous silicon layer to perform a crystallization process. Various crystallization methods such as a lithography method, a laser method, and so on, may be used for the crystallization process.

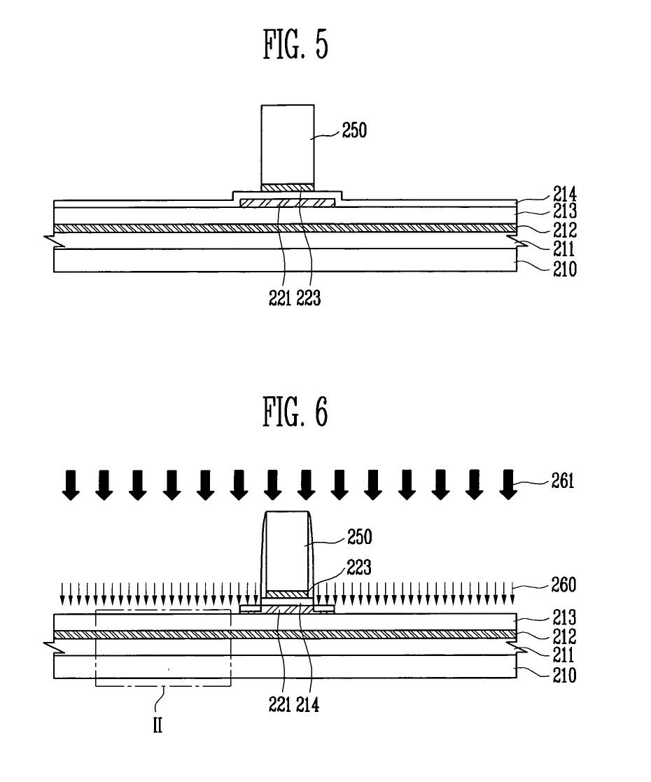

FIG. 4A is an enlarged view of a region (I) in FIG. 3, and FIGS. 4B and 4C are photographs showing a state of deformation of a plastic substrate resulting from different amounts of laser irradiation of the region (I). In the embodiment, the plastic substrate is formed of arylite, a first buffer layer 211 formed of oxide is deposited to a thickness of 2500 Å on the substrate, and a laser-absorbing layer 212 formed of silicon (Si) is deposited to a thickness of 800 Å on the first buffer layer 211. A second buffer layer 213 formed of oxide is deposited to a thickness of 2700 Å on the laser-absorbing layer 212, and a silicon layer to be used as the active layer 221 is deposited to a thickness of 800 Å on the second buffer layer 213. FIG. 4B is a photograph showing the state of deformation of the plastic substrate 210 when the aforementioned structure is irradiated with 750 mJ/cm² of laser light, and FIG. 4C is a photograph showing the state of deformation of the plastic substrate 210 when the aforementioned structure is irradiated with 800 mJ/cm² of laser light. As a result of the photographed substrate according to the test, it will be appreciated that the plastic substrate 210 is not deformed although laser light or heat with high energy is irradiated onto the plastic substrate 210.

FIGS. 5 and 6 are cross-sectional views showing manufacturing processes after the manufacturing process of FIG. 3. Referring to FIG. 5, the active layer 221 is formed by etching the polysilicon layer crystallized by the crystallization process of FIG. 3. After forming the active layer 221, a gate dielectric material having insulation characteristics (hereinafter, referred to as a gate insulating layer 214) is deposited on the active layer 221. Then, a gate metal 223 is deposited on the gate insulating layer 214. At this time, the gate metal 223 is formed of a material having a high reflectivity, e.g., aluminum, and so on. Next, a first photoresist (P/R) 250 is spin-coated on the gate material 223, and then a mask (not shown) is covered over the first photoresist 250 to perform a photolithography process, thereby etching the gate metal 223. Then, a process of baking the first photoresist 250 is performed at a temperature of about 140° C. in an oven to prevent the first photoresist 250 from being developed more.

Referring to FIG. 6, a process following the bake process will be described. A second photoresist 251 is spin-coated on the gate metal 223, and then exposed without any mask. When the exposure process is performed, the baked first photoresist 250 is not developed, and a thick part of the second photoresist 251 remains to form a spacer. Next, when the gate insulating layer 215 is etched, an offset region corresponding to the spacer is formed between the active layer 221 and the gate metal 223. Then, the first and second photoresist 250 and 251 are stripped, and then a doping process is performed to be activated. In the embodiment, after performing an ion shower doping process, a laser 261 is used for the activation. At this time, the doped polysilicon region is activated by the laser 261, and the offset region which is not doped is not activated. In addition, the laser light is transmitted to the laser-absorbing layer 212 through the second buffer layer 213 to be absorbed into the region (II) to which the second buffer layer 213 is exposed.

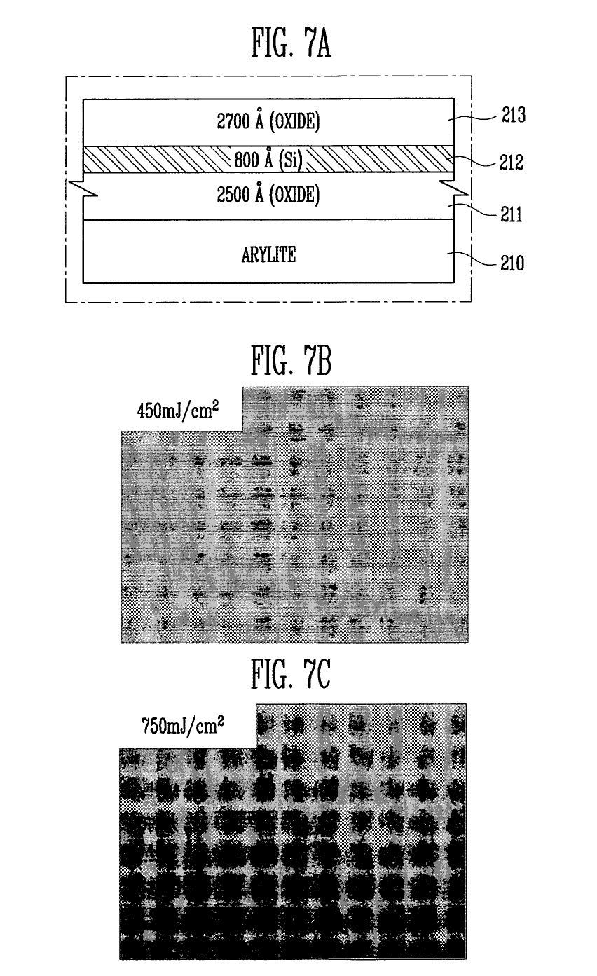

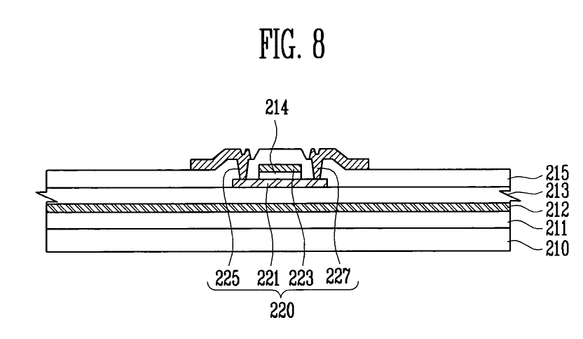

FIG. 7A is an enlarged view of a region (II) in FIG. 5, and FIGS. 7B and 7C are photographs showing a state of deformation of a plastic substrate resulting from different amounts of laser irradiation of the region (II). Referring to FIG. 7A, the plastic substrate 210 is formed of arylite, a first buffer layer 211 formed of oxide is deposited on the substrate to a thickness of 2500 Å, a laser-absorbing layer 212 is deposited to a thickness of 800 Å on the first buffer layer 211, and a second buffer layer 213 formed of oxide is deposited on the laser-absorbing layer 212 to a thickness of 2700 Å. FIG. 7B is a photograph showing the state of deformation of the plastic substrate 210 when the aforementioned structure is irradiated with 450 mJ/cm² of laser light, and FIG. 7C is a photograph showing the state of deformation of the plastic substrate 210 when the aforementioned structure is irradiated with 750 mJ/cm² of laser light. As a result of the photographed substrate according to the test, it will be appreciated that the plastic substrate is not deformed although a laser light of 450 /cm²˜750 mJ/cm² is irradiated onto the plastic substrate 210. Generally, since an energy of 450 mJ/cm²˜600 mJ/cm² is required to activate the plastic substrate, when the laser-absorbing layer 212 is formed between the first and second buffer layers 211 and 213, it will be appreciated through the test that the plastic substrate 210 is not deformed. In addition, when the laser-absorbing layer 212 contains hydrogen, or when hydrogen is injected into the laser-absorbing layer 212, hydrogen passivation can be formed to prevent the deformation of the plastic substrate 210.

The following processes will now be described with reference to FIG. 8. After forming an active layer 221 and a gate metal 223, an interlayer insulating layer 215 is deposited on the active layer 221 and the gate metal 223. Subsequently, contact holes (not shown) are formed in the interlayer insulating layer 215, and then source and drain electrodes 225 and 227 are formed. A thin film transistor 220 is formed by the processes. Next, a capacitor 230 and a light emitting diode 240 electrically connected to the thin film transistor 220 are formed. The process of manufacturing the capacitor 230 and the light emitting diode 240 is similar to well-known technology; and thus their descriptions will be omitted.

As can be seen from the foregoing, the present invention can prevent deformation of a plastic substrate although an amorphous silicon layer is crystallized using various crystallization apparatuses by forming a laser-absorbing layer capable of absorbing light or heat between a plurality of buffer layers.

In addition, when the laser-absorbing layer contains hydrogen, it is possible to provide a hydrogen passivation effect due to the hydrogen.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. An active matrix driving display device comprising:
a first buffer layer formed on a plastic substrate;
a laser-absorbing layer formed on the first buffer layer;
a second buffer layer formed on the laser-absorbing layer; and
an active layer formed on the second buffer layer.

2. The active matrix driving display device according to claim 1, wherein the laser-absorbing layer has a thickness of 100˜2000 Å.

3. The active matrix driving display device according to claim 2, wherein the laser-absorbing layer is formed of a material absorbing laser light irradiated from the top of the plastic substrate.

4. The active matrix driving display device according to claim 3, wherein the laser-absorbing layer contains amorphous silicon or molybdenum.

5. The active matrix driving display device according to claim 1, wherein each of the first and second buffer layers has a thickness of 1000˜5000 Å.

6. The active matrix driving display device according to claim 5, wherein the first buffer layer and the second buffer layer are formed of oxide or nitride.

7. The active matrix driving display device according to claim 1, wherein the active layer has a melting point relatively higher than that of the first buffer layer, the second buffer layer, and the laser-absorbing layer.

8. The active matrix driving display device according to claim 1, further comprising: a thin film transistor formed on the active layer and having a gate electrode, a source electrode, and a drain electrode; and a capacitor and an organic light emitting diode which are electrically connected to the thin film transistor.

9. A method of manufacturing an active matrix driving display device, comprising:
forming a first buffer layer on a plastic substrate;
forming a laser-absorbing layer on the first buffer layer;
forming a second buffer layer on the laser-absorbing layer; and
forming an active layer on the second laser-absorbing layer.

10. The method according to claim 9, wherein forming the active layer comprises:
depositing an amorphous silicon layer on the second buffer layer; and
crystallizing the deposited amorphous silicon layer.

11. The method according to claim 10, further comprising:
forming a thin film transistor having the active layer, and a gate electrode, a source electrode, and a drain electrode which are formed on the active layer; and
forming a light emitting diode electrically connected to the thin film transistor.
